(19) United States
(12) Patent Application Publication
(10) Pub. No.: US 2026/0293552 A1
(43) Pub. Date: Sep. 24, 2026

(54) ION BEAM DIRECTIONAL DEPOSITION AND ETCH

(71) Applicant: Axcelis Technologies, Inc., Beverly, MA (US)

(72) Inventor: Glen Gilchrist, Wingdale, NY (US)

(21) Appl. No.: 19/573,159

(22) Filed: Mar. 20, 2026

Related U.S. Application Data
(60) Provisional application No. 63/774,999, filed on Mar. 20, 2025.

(51) Int. Cl. H10P 50/24; H10P 14/60; H10P 50/28

(52) U.S. Cl. CPC H10P 50/244; H10P 14/6329; H10P 50/283

(57) ABSTRACT

Processes for modifying an extreme ultraviolet (EUV) pattern generally includes sequentially directionally depositing a sacrificial liner layer and etching to provide a modified EUV pattern. The process includes directionally depositing a sacrificial liner layer by ion beam onto selected surfaces of the EUV pattern; twisting the pattern 90° such that the sacrificial liner layer is aligned in a y-direction; and directionally etching the pattern in the y-direction to form a modified pattern. Then apparatus can include a double plasma ion source for both ion beam directional deposition of silicon compounds, siloxane compounds or the like and directional etch using etchants such as SiF₃⁺.

### CROSS REFERENCE TO RELATED APPLICATIONS

This application claims the benefit of priority to U.S. Provisional Application No. 63/774,999, filed on Mar. 20, 2025, which is incorporated by reference in its entirety herein.

### BACKGROUND

The present disclosure generally relates to integrated circuit fabrication and equipment, and more specifically, to ion beam directional deposition and etching processes and equipment for improving pattern fidelity associated with features formed using extreme ultraviolet (EUV) lithography.

EUV lithography is a next-generation lithography technique that utilizes 13.5 nanometer (nm) wavelength light to print extremely fine features for advanced semiconductor manufacturing, enabling nodes at 7 nm, 5 nm, and beyond. The chemical photoresists used in EUV lithography must balance sensitivity, resolution, and etch resistance. Current photoresists struggle to provide high-resolution patterning without compromising line-edge roughness, local critical dimension (CD) variations, or stochastic defects that can affect device performance and yield. Other limitations associated with EUV photoresist patterning include mismatches between the designed pattern provided by a mask and the printed pattern which, in turn, can lead to poor interconnect alignment, high contact resistance, excess power consumption and heat generation. Some mismatches can be corrected by double patterning, but this is expensive, time consuming, and increases the fab bottleneck at the patterning module.

Prior art FIG. 1 illustrates top-down views of four (4) exemplary interconnect structures 10, 20 as designed and as lithographically patterned and mismatched, respectively. The designed interconnect structures 10 includes trench structures 14 formed in layer (L), lower level vias 12 formed in underlying layer (L−1), and upper level vias 16 formed in overlying layer (L+1). As shown, the design pattern for the trench structures 14 in layer (L) has a rectangular shape with sharp corners and the vias 12, 16 intended to be formed in the underlying and overlying layers (L−1) and (L+1), respectively, are aligned to each end of the trench structures 14.

However, pattern fidelity after EUV lithographic patterning is not maintained and can lead to mismatches from the designed interconnect structure. Because of the limitations associated with current EUV photoresists and EUV lithography systems used to pattern the EUV photoresists, the lithographically patterned interconnect structure 20 includes patterned trench structures 24 that can include rounded ends, have a shorter length dimension, include bridge defects, include sidewalls therein that may not be completely vertical, or the other like deviations from the designed interconnect structure 10. As a result of these limitations, oftentimes there is a mismatch of the underlying and overlying vias 22, 26, respectively, to the patterned trench structures 24 for the patterned interconnect structure 20 as shown, which can result in partial via overlap at the ends of the patterned trench structures 24. The mismatch of the patterned vias to the patterned trench structures can lead to high resistance and generation of excess heat, which can result in premature failure of the integrated circuit. Some mismatches can be corrected such as by EUV double patterning, which is not very practical since it can significantly increases costs given the increased throughput times and can cause bottlenecking at the patterning module.

### BRIEF SUMMARY

Disclosed herein are processes for modifying a pattern formed by extreme ultraviolet lithography. In one or more embodiments, a process for modifying a pattern formed by extreme ultraviolet lithography includes forming the pattern including trench and/or line features. A sacrificial liner layer is deposited by ion beam onto sidewalls of the trench and/or line features, wherein the trench and/or line features are aligned in a longitudinal direction corresponding to a length dimension of the trench and/or line features. The pattern is rotated 90° such that the trench and/or line features are orthogonally aligned to the longitudinal direction; and the pattern is directionally etched to form a modified pattern. Directionally depositing the sacrificial liner layer and etching utilizes a double plasma ion source to produce an ion beam from a gas supply configured to directionally deposit the sacrificial liner layer and directionally etch the pattern to form the modified pattern. Deposition of the sacrificial line can be non-directional and may be executed in a separate chamber and/or tool while the etch is directional. In other embodiments, deposition of the sacrificial liner layer and directionally etching are generated by a radio frequency (RF), microwave (MW), electron cyclotron resonance (ECR) plasma ion source. The gas supply for depositing the sacrificial liner layer can include silanes or siloxanes. The gas supply for directionally etching the pattern can include SiF₄ and the ion source is configured to generate SF₃⁺. The sacrificial liner layer can be removed during the etching. In one or more embodiments, depositing the sacrificial liner layer by ion beam onto the sidewalls includes depositing the sacrificial liner layer onto a selected one of the sidewalls in the longitudinal direction followed by 180° rotation and depositing the sacrificial liner layer onto the other one of the sidewalls in the longitudinal direction. The trench feature can be rotated 90° such that a selected end of the trench feature is directionally etched before the sacrificial liner layer has been partially or completely removed to form a substantially square profile followed by rotation of the trench feature by 180° to directionally etch another end of the trench feature to form a substantially square profile at the other end. In one or more embodiments, the trench and/or line feature further comprises one or more bridge defects removed by the directional etching. In one or more embodiments, deposition of the sacrificial liner layer and directional etching is at a wafer tilt of 45 to 70°. The process can further include in situ cleaning subsequent to forming the modified pattern to remove residues.

In one or more embodiments, a process to modify a pattern including circular vias includes directionally etching the pattern comprising circular vias in a first direction; rotating the pattern 90° and directionally etching the pattern comprising circular vias in a second direction; repeating rotating the pattern 90° and directionally etching the pattern in third and fourth directions. The pattern is rotated 45° and a liner layer is directionally deposited in a fifth direction. The pattern is rotated 90° and the liner layer is directionally deposited in a sixth direction; Rotating the pattern 90° is repeated and directionally etched in seventh and eighth directions to form a modified pattern of the circular vias having a substantially square profile. Directionally etching and directionally depositing the liner layer can utilize a double plasma ion source to produce an ion beam from a gas supply configured to directionally etch and directionally deposit the liner layer. In one or more embodiments, directionally depositing the liner layer and directionally etching is at a wafer tilt of 45 to 70°.

In one or more embodiments, a process to reduce tip-to-tip spacing between lines and/or trenches from using extreme ultraviolet lithography includes patterning line, via and/or trench features using extreme ultraviolet lithography along a longitudinal direction, wherein adjacent lines, vias and/or trench features along a common axis in the longitudinal direction are spaced apart from one another. A sacrificial liner layer is deposited by ion beam onto sidewalls along a longitudinal direction of the patterned lines, vias and/or trench features. The patterned lines, vias and/or trench features are rotated 90° such that the patterned lines and/or trench features are aligned in a y-direction; and directionally etched in the y-direction to reduce the spacing between the adjacent lines, vias and/or trench features. Directionally depositing the sacrificial liner layer and etching can utilize a double plasma ion source to produce an ion beam from a gas supply configured to directionally deposit the sacrificial liner layer and directionally etch. The gas supply configured to directionally deposit the sacrificial liner layer can include silanes, or siloxanes; and the gas supply configured to etch can include SiF₄ to generate SF₃⁺. In other embodiments, directionally depositing the sacrificial liner layer and directional etching is at a wafer tilt of 45 to 70°. In still other embodiments, the patterned lines and/or trenches comprises one or more bridge defects that are removed by the directional etching. The patterned lines and/or trenches can be directionally etched before the sacrificial liner layer has been partially or completely removed to form substantially square profiles at an end of the patterned lines and/or trenches.

These and other objects, advantages and features of the disclosure will become better understood from the detailed description of the disclosure that is described in conjunction with the accompanying drawings.

### BRIEF DESCRIPTION OF DRAWINGS

Prior Art FIG. 1 illustrates plan views of four (4) exemplary prior art interconnect structures as designed and as lithographically patterned with an extreme ultraviolet photoresist;

FIG. 2 illustrates plan views of trench structures lithographically patterned using an extreme ultraviolet photoresist and subsequently subjected to sequential directional deposition and directional etch to increase pattern fidelity in accordance with one or more embodiments of the present disclosure;

FIG. 3 plan views of a trench structure lithographically patterned using an extreme ultraviolet photoresist including a bridge defect and subsequently subjected to sequential directional deposition and directional etch to remove the bridge defect and increase pattern fidelity in accordance with one or more embodiments of the present disclosure;

FIG. 4 is a plan view of a circular via structure lithographically patterned using an extreme ultraviolet photoresist and subsequently subjected to sequential directional etch and directional deposition to modify the circular shaped via to a substantially square shaped via structure in accordance with one or more embodiments of the present disclosure; and

FIG. 5 is a plan view of a patterned dense line structure with a relaxed tip-to-tip spacing lithographically patterned using an extreme ultraviolet photoresist and subsequently subjected to sequential directional deposition and directional etch to reduce the tip-to-tip spacing in accordance with one or more embodiments of the present disclosure.

FIG. 6 is a plan view of a patterned circular-like via structure with a relaxed spacing lithographically patterned using an extreme ultraviolet photoresist and subsequently subjected to sequential directional deposition and directional etch to modify the circular-like vias to elliptical shaped vias with reduced spacing in accordance with one or more embodiments of the present disclosure; and

FIG. 7 illustrates an exemplary ion implantation system including a double plasma ion source suitable for sequential directional deposition and directional etch in according to another aspect of the present invention.

### DETAILED DESCRIPTION

The present disclosure is generally directed to apparatuses and processes for photoresist pattern modification (e.g., such as formed by EUV lithography) by sequential ion beam directional deposition and etch processing. Advantageously, mismatches between the EUV patterned layers defining the interconnect structures or other types of defects, e.g., tip-to-tip and bridge defects, can be corrected and double patterning processes eliminated by a one-dimensional EUV patterning modification process including sequential ion beam directional deposition of a sacrificial liner followed by an etch process in accordance with the present disclosure. The process generally includes placing a substrate including an EUV lithographically patterned photoresist layer into an apparatus configured to sequentially provide ion beam directional deposition of a sacrificial liner layer followed by etch. The directional deposition and directional etch is at relatively high tilt, e.g., 45° to 70° so as to minimize CD loss. Moreover, high tilt is particularly beneficial when sidewalls are less than 90° in order to minimize ion flux to the sidewall. The particular apparatus is not intended to be limited and can include an individual ion beam directional deposition module and an etch module or an apparatus configured to sequentially provide both ion beam directional deposition and etch with the same ion source such as the double plasma ion source system described in U.S. Pat. No. 7,947,966 to Axcelis Technologies, Inc., which is incorporated herein by reference in its entirety.

The pattern modification process generally includes placing a substrate including the patterned features and depositing a sacrificial liner layer on the sidewalls of the feature by ion beam directional deposition. The thickness of the sacrificial liner layer can generally be about 1 to about 3 nanometers (nm) although greater or lesser thicknesses for different types and sizes of features may be used as will be appreciated by those skilled in the art. Lines and/or trench features are aligned along a longitudinal direction (e.g., x-direction) so that sacrificial liner layer deposition occurs primarily on the sidewalls along the longitudinal dimension of the features. For example, trench features for interconnect structures can be longitudinally aligned lengthwise in the x-direction prior to ion beam directional deposition of a sacrificial liner layer primarily on a selected one of the sidewalls along the longitudinal dimension of the trench feature, which will then be rotated 180° and subjected to ion beam directional deposition of the sacrificial liner layer primarily on the other one of the sidewalls along the longitudinal dimension of the trench feature.

The substrate, i.e., the trench features are then rotated 90° and subsequently etched along a transverse or orthogonal direction with respect to the longitudinal direction (e.g., y-direction) so as to modify one end of the trench feature as initially patterned. Deployment of the sacrificial liner prevents x-axis critical dimension (CD) loss while the substrate is twisted to 90° and etched parallel to the y axis so that the dy/dx change can be >>100. The substrate is then rotated 180° and the other end of the trench feature is etched. The resulting modified trench feature can thus be configured to have a pattern fidelity more closely aligned with the intended design provided by a mask. That is, the original EUVL patterned trench feature having an elliptical-like shape is modified to have a rectangular-like shape. Advantageously, by directionally depositing a sacrificial material on the sidewalls of a patterned trench, rotating the wafer by 90°, and performing a directional etch, material removal in one direction may be on the order of around 20 times or more than in the orthogonal direction. This has the advantage of modifying a pattern feature in one direction without materially altering the feature in the orthogonal direction. In a similar manner, patterned circular or oval vias can be modified to form square or rectangular vias as will be described in greater detail below. Likewise, the sequential directional deposition directional etch can be used to minimize tip-to-tip spacing as well as remove bridge defects, which will also be described in greater detail below.

The terms “tip-to-tip” and “bridge defects” generally refers to defects in EUV lithography that arise due to the sensitivity of extreme ultraviolet exposure to small spacing variations between features. When two line-ends or shapes are too close, stochastic effects—such as photon shot noise, resist variability, and mask imperfections—can lead to bridging, line-end shortening, or local CD (critical dimension) variation. Bridge defects can also occur in dense design features, e.g., patterned lines and spaces, where small stochastic variations can cause nearby lines to merge. Still further, bridge defects can occur between closely spaced contact/via holes due to pattern fidelity issues. These defects can cause electrical shorts in circuits or pattern fidelity issues that degrade yield and/or cause catastrophic failure. Tip-to-tip push techniques can be used to mitigate these defects by slightly increasing the spacing between closely positioned features, improving the process window and reducing pattern collapse risks. However, excessive push can lead to unwanted layout distortions or connectivity issues, requiring careful tuning during design rule and optical proximity correction (OPC) optimizations. The sequential ion beam directional deposition and etching process in accordance with the present disclosure advantageously reduces defects by optimizing tip-to-tip spacing by pattern modification to provide tight spacing without the need for optical proximity correction (OPC) optimizations, push techniques, or the like. Likewise, bridge defects can be removed, which can occur when photoresist lines fail to fully separate after development, leading to resist bridges that distort the intended pattern. This can be catastrophic in semiconductor circuits, potentially causing electrical shorts and yield loss.

For the purposes of the description hereinafter, the terms “upper”, “lower”, “top”, “bottom”, “left,” and “right,” and derivatives thereof shall relate to the described structures, as they are oriented in the drawing figures. The same numbers in the various figures can refer to the same structural component or part thereof. Additionally, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

Spatially relative terms, e.g., “beneath,” “below,” “lower,” “above,” “upper,” and the like, can be used herein for ease of description to describe one element or feature's relationship to another element(s) or feature(s) as illustrated in the figures.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the term “about” modifying the quantity of an ingredient, component, or reactant of the disclosure employed refers to variation in the numerical quantity that can occur, for example, through typical measuring procedures used for making component mixtures. Furthermore, variation can occur from inadvertent error in measuring procedures, differences in the manufacture, source, or purity of the ingredients employed to make the compositions or carry out the methods, and the like.

It will also be understood that when an element, such as a layer, region, or substrate is referred to as being “on” or “over” another element, it can be directly on the other element or intervening elements can also be present. In contrast, when an element is referred to as being “directly on” or “directly over” another element, there are no intervening elements present, and the element is in contact with another element.

The ion beam and etching apparatuses in accordance with the present disclosure are not intended to be limited and can be individual modules or a dual module apparatus. In order to maximize throughput, the apparatus can be a dual module apparatus configured to provide sequential ion beam directional deposition and etch. An exemplary dual module apparatus is a double plasma ion source system such as that described in U.S. Pat. No. 7,947,966 entitled Double Plasma Ion Source to Axcelis Technologies, Inc., which is incorporated by reference in its entirety. The double plasma ion source system described therein, which is not intended to be limiting, can be utilized for sequential directional deposition and etching. For example, the patent for the double plasma ion source system disclosed yielding high quantities for both large molecular ions (B₁₀H₁₄ and B₁₈H₂₂ were given as examples) and standard implant gases like SiF₄, BF₃, PH₃, AsH₃. The dual capability of the double plasma ion source system can be configured to provide sequential directional deposition and etch using candidate species such as high molecular weight silicon compounds for directional deposition such as, but not limited to, Si₄H₁₀, Si₃H₈, Si₂F₆, or siloxanes such as [(CH₃)₂SiO]₅ or the like; and can be configured to sequentially run SiF₃⁺ or the like for etch using the same ion source that is used for directional deposition. Moreover, the double plasma ion source system can advantageously be configured to provide in situ cleaning chemistry (e.g., O₂, NF₃, and the like) to remove photoresist residues and etch residues that may result from the sequential ion beam directional deposition and etch.

Accordingly, the present disclosure will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth to provide a thorough understanding of the present invention. It will be evident to one skilled in the art, however, that the present disclosure may be practiced without these specific details. Further, the scope of the disclosure is not intended to be limited by the embodiments or examples described hereinafter with reference to the accompanying drawings but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling.

As noted above, the present disclosure is generally directed to EUV pattern modification and/or defect removal using ion beam directional deposition to form a sacrificial liner layer on sidewalls of a patterned feature such as along a length dimension of a trench or line feature and sequentially etch the patterned feature with the sacrificial liner layer to modify and provide improved pattern fidelity of the EUV patterned features more closely approximating the intended design.

Ion beam techniques are widely used in semiconductor processing, thin-film deposition, and nanofabrication. These techniques allow for highly directional material addition (deposition) with precise control over layer thickness and composition. Ion beam deposition is a physical vapor deposition (PVD) method where the ion beam is used to assist in the deposition process that uses an energetic ion beam to influence the growth of thin films. It allows for highly controlled, directional deposition. Typically, a plasma ion source such as argon is used to generate ions, which are accelerated and focused into a collimated beam using electrostatic or magnetic lenses. The ion beam bombards a solid target, causing atoms or molecules to be ejected (sputtered) due to momentum transfer. The sputtered atoms or molecules travel in a straight-line trajectory toward the substrate. The angle of ion incidence can be adjusted to control film structure and density. The ejected material condenses and forms a thin film on the substrate. A secondary assisting ion beam may be used to further tailor film properties by modifying atomic arrangement. In the present disclosure, the ion source is selected to operate with low source wall temperature and low discharge power for directional deposition of large molecule gases such as Si₄H₁₀, Si₃H₈, Si₂F₆ [(CH₃)₂SiO]₅ decamethylcyclopentasiloxane, or other large siloxanes, (so-called “molecular species”) and with high wall temperature and high discharge power for etch.

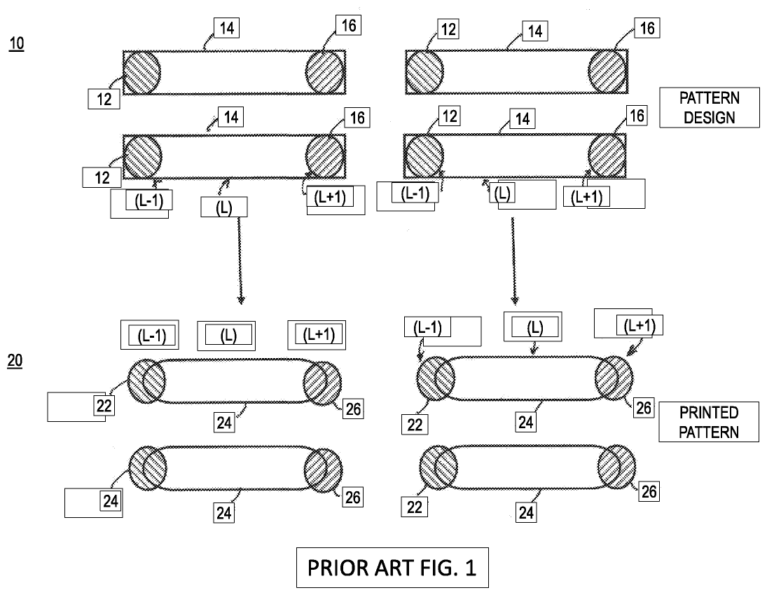

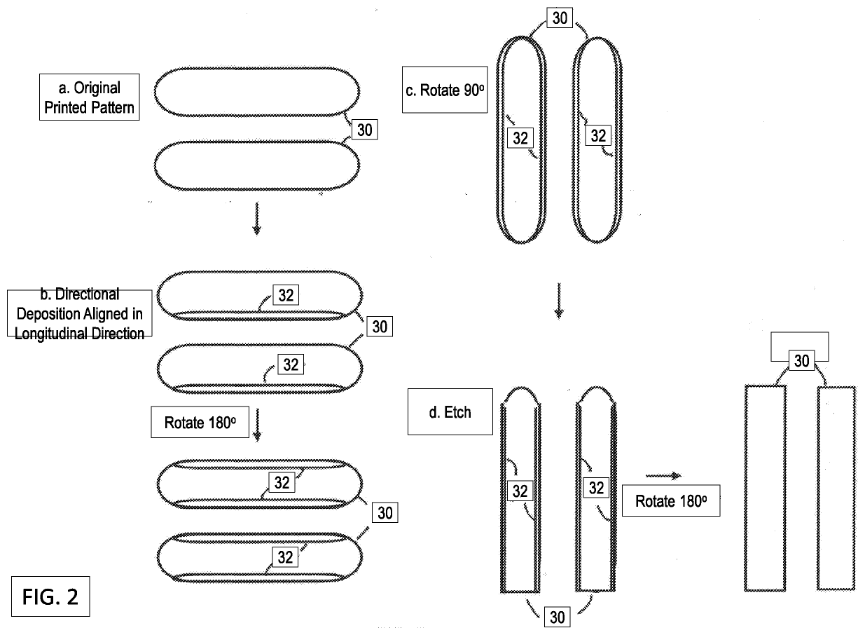

Turning now to FIG. 2, there is shown modification of a EUVL trench pattern by sequential ion beam direction deposition and etch in accordance with an embodiment of the present disclosure. In Step a. the patterned trench features, which typically deviate from the designed pattern as evidenced by the rounded ends as opposed to square ends and shorter lengths, are rotated on an electrostatic chuck, for example, such that the trench feature is horizontally aligned in the x-direction, corresponding to a longitudinal direction of the trench feature. In step b., a sacrificial liner layer 32 such as a silicon compound or a siloxane (SiOₓ) compound is directionally deposited by ion beam primarily onto a selected one of the sidewalls of the trench feature 30, i.e., the opposing or distally positioned side wall relative to the ion source aperture. The substrate is then twisted 180° so that the sacrificial liner layer can be deposited on to the other sidewall. By way of example, the thickness of the sacrificial liner 32 can be about 2 nm.

In step c., the trench features 30 are rotated 90° and vertically aligned in the y-direction, i.e., orthoganol or transverse to the longitudinal direction of the trench feature 30 in the previous step.

In step d., the opposing end of each trench feature is then directionally etched with a desired ion flux to modify the rounded profile to a square-like profile at the selected end of the trench feature 30. Referring to the 2 nm thickness for the sacrificial liner layer 32 previously deposited on the trench sidewalls, the directional ion flux (x/y) can be at a directional ratio of 10 so that 20 nm in the y-direction can be etched before the sacrificial liner layer 32 is completely removed. The substrate is rotated 180° to modify the other end of trench feature 30 to form substantially square profiles at each end in contrast to the radial profiles at the trench ends in the original EUVL pattern. The process is complete when dy=20 nm in the y direction. For greater tip-to-tip push, one can use multiple cycles or thicker deposition. The substrate including the trench features can then be subject to an optional in situ clean to remove any residues.

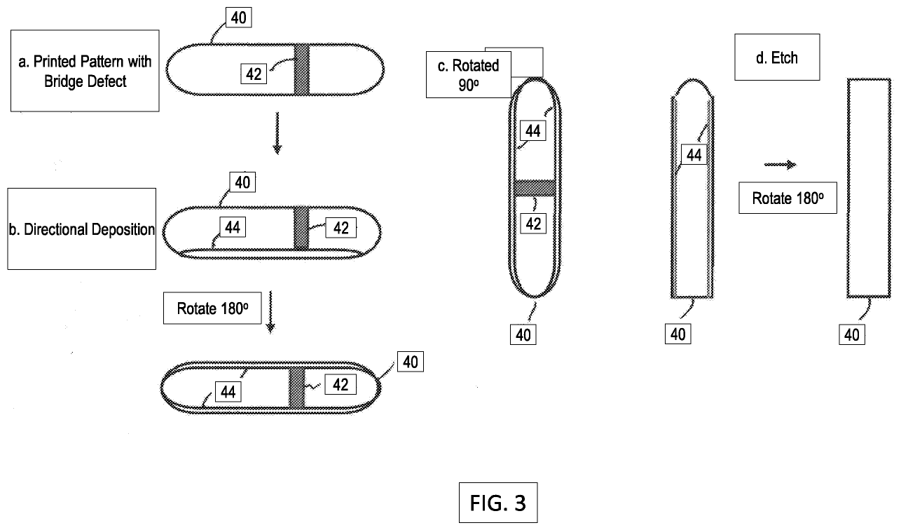

FIG. 3 illustrates bridge defect removal/descum and pattern modification for a trench feature 40 by ion beam direction deposition and etch in accordance with an embodiment of the present disclosure. In Step a. the trench features are rotated such that the length dimension of the trench feature is horizontally aligned in the x-direction, i.e., the longitudinal direction. The bridge defect is designated by reference numeral 42. In step b., a sacrificial liner layer 44 is directionally deposited primarily onto the sidewalls of the trench feature 40 as previously described. By way of example, the thickness of the deposited sacrificial liner layer 44 can be about 1 nm and the substrate rotated 180° in the manner previously discussed so that each horizontal sidewall in the longitudinal direction can include the sacrificial liner layer 44 of the same thickness. In step c., the trench features 40 are rotated 90° such that the trench feature is vertically aligned in the y-direction. The trench features 40 are then directionally etched with a desired ion flux to remove the bridge defect and to then square each of the ends of the trench feature 40. Referring to the 1 nm thick sacrificial liner layer 44, the directional ion flux (x/y) for etching can be 20 so that bridge defects up to 20 nm in the y-direction can be etched before the sacrificial liner layer 44 is removed. The substrate can be rotated 180° to modify the trench pattern ends to form square profiles in contrast to the radial profile of the original EUVL pattern. The process is complete when dx=0 nm. For thicker bridge defects, one can use multiple cycles or a thicker sacrificial liner layer deposition. The substrate can then be subject to an optional in situ clean to remove any residues.

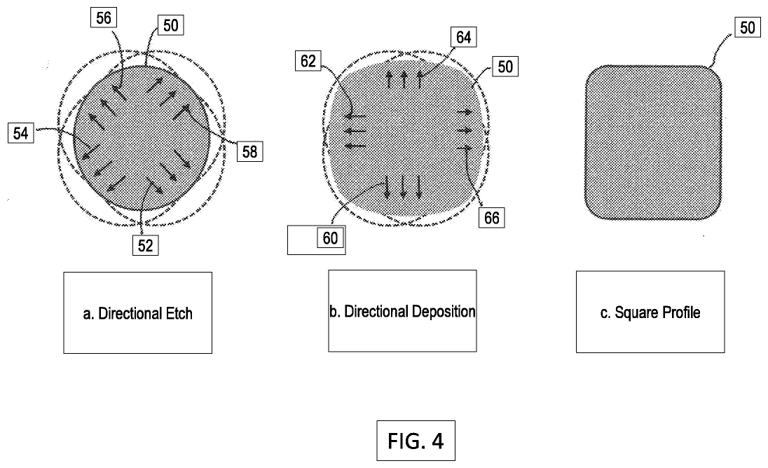

FIG. 4 illustrates pattern modification of a circular via feature 40 by ion beam directional etch followed by directional deposition and in accordance with an embodiment of the present disclosure to form a square shaped via, which can be utilized to provide greater overlap with the trench feature, for example. In step a., one or more circular vias 50 are first formed by EUVL, each of which is then subjected to directional etch as indicated by arrows 52, 54, 56, 58 to remove material to about the dotted line structure. The substrate is rotated 90° for each directional etch to alter the circular shape of the vias 50. In step b., the modified vias are subject to directional deposition of a liner layer as indicated by arrows 60, 62, 64, and 66. Relative to the direction of the directional etch, the directional deposition of sacrificial material begins at 45° for the first deposition step followed by 90° rotation for each subsequent deposition to further define a square profile as shown in step c, which generally corresponds to the dotted line structure. As previously noted, modifying circular vias to provide a square-like profile that is larger than the original patterned via can help provide better overlap within the interconnect structure should there be any mismatch.

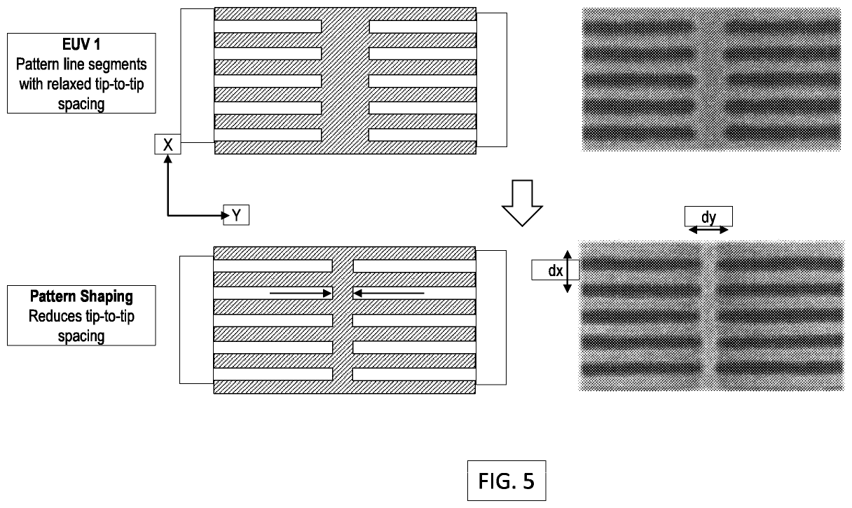

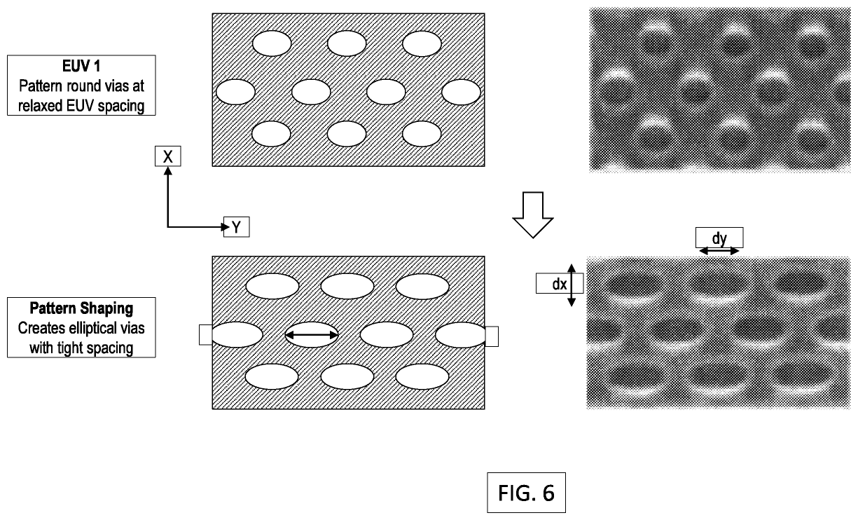

The capability to deposit a sacrificial liner and directionally etch in rapid sequence as described above is a distinct advantage for EUV pattern shaping and pattern modification. For EUV pattern modification, the line sidewall may be protected by deposition of the sacrificial liner, composed of Si, SiO₂, or the like that will be etched concurrently with the tip-to-tip (TTT) push, which are pictorially shown in FIGS. 5 and 6. In FIG. 5, tip-to-tip spacing between patterned line features can be relaxed and then modified to reduce the tip-to-tip spacing as shown. Likewise, as shown in FIG. 6, spacing between circular vias can be relaxed initially and subsequently patterned to form elliptical vias with minimal spacing between adjacent vias.

Deployment of the sacrificial liner in accordance with the methods described herein will prevent x axis CD loss while the device is etched parallel to the y axis so dy/dx can be >>100 as may be desired for different applications.

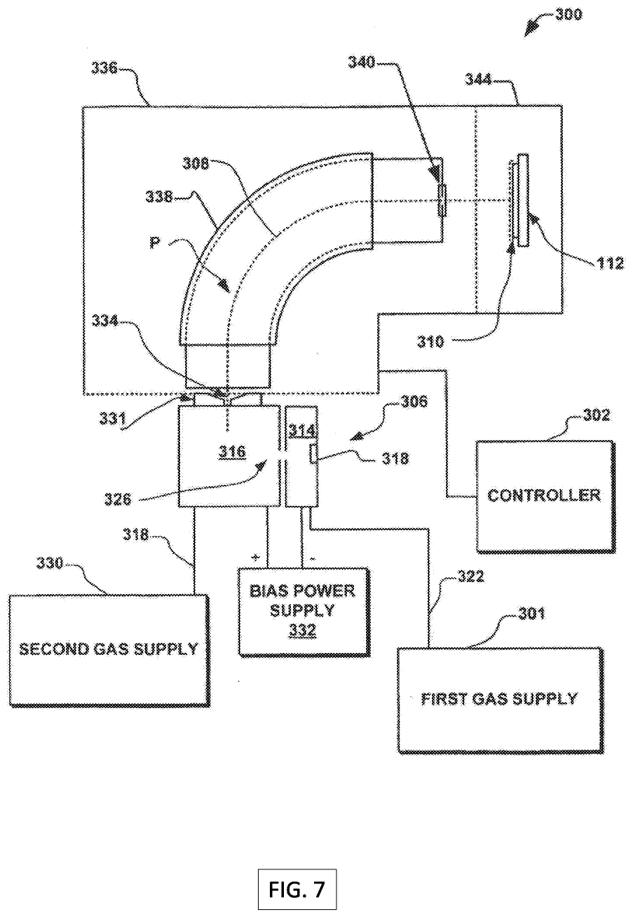

An exemplary ion implantation system 100 configured to provide rapid sequential directional deposition and directional etch is schematically depicted in FIG. 7. The ion implantation apparatus 100 is operably coupled to a controller 102 for controlling the various operations and processes implemented on the ion implantation apparatus 100. In accordance with the present invention, the ion implantation apparatus 100 includes the double plasma ion source assembly 106 for producing a quantity of ions for generating an ion beam 108 traveling along an ion beam path P, for implantation of the ions to a workpiece 110 (e.g., a semiconductor workpiece, display panel, etc.) held on a workpiece support platen 112. The ions can be formed from inert gases such as argon (Ar) and xenon (Xe), reactive gases such as oxygen (O₂) and nitrogen trifluoride (NF₃) for in situ cleaning, etchant gases such as SiF₄ for generating SiF₃ ⁺, and large molecule gases such as silicon containing molecules such as Si₄H₁₀, Si₃H₈, Si₂F₆, or siloxanes such as [(CH₃)₂SiO]₅, or the like.

The ion source assembly 106, comprises a first plasma chamber 114 (e.g., a plasma chamber or arc chamber) and a second plasma chamber 116, wherein the first plasma chamber 114 is configured with a plasma generating component 118, which can include a cathode 108 and an anode 110 for generating a plasma from a first gas introduced into the first plasma chamber 114 via a first gas feed line 122 from a first gas supply 101. The cathode 108 may include a simple Bernas-type filament configuration, or an indirectly heated cathode. The plasma generating component 118 can, in the alternative, comprise an RF induction coil, for example, that is supported having a radio frequency conducting segment mounted directly within a gas confinement chamber to deliver ionizing energy into the gas ionization zone. The first gas can comprise at least one of the following: inert gases such as argon (Ar) and xenon (Xe), etchant gases for generating SiF₃⁺ or the like and reactive gases such as oxygen (O₂) and nitrogen trifluoride (NF₃).

A second plasma chamber 116 is situated in fluid communication with the first plasma chamber 114 via a common boundary aperture 126 formed between the first and second plasma chambers, 114 and 116, wherein the second plasma chamber 116 contains a second gas introduced by a second gas feed line 128 from a second gas supply 120. The second gas can include large molecule gases as described above.

The second plasma chamber 116 can be biased positive with respect to the first plasma chamber 114 by a bias power supply 132, enabling the extraction of electrons from the first plasma chamber 114 for injection into the second plasma chamber 116. When the extracted electrons collide with the second gas in the second plasma chamber 116 they create a plasma in the second plasma chamber 116. An extraction aperture 134 is provided in the second plasma chamber 116 to extract ions from the plasma formed therein.

The ion implantation system 100 further comprises an extraction electrode assembly 131 associated with source assembly 106, wherein the extraction electrode assembly 131 is biased to attract charged ions from the source assembly 106 for extraction through the extraction aperture. A beamline assembly 136 is further provided downstream of the ion source assembly 106, wherein the beamline assembly 136 generally receives the charged ions from the source 106. The beam line assembly 136, for example, comprises a beam guide 142, a mass analyzer 138, and a resolving aperture 140, wherein the beam line assembly 136 is operable to transport the ions along the ion beam path P for implantation into workpiece 110.

The mass analyzer 138, for example, further comprises a field generating component, such as a magnet (not shown), wherein the mass analyzer 138 generally provides a magnetic field across the ion beam 108, thus deflecting ions from the ion beam 108 at varying trajectories according to a charge to mass ratio associated with the ions extracted from the source 106. For example, ions traveling through the magnetic field experience a force that directs individual ions of a desired charge to mass ratio along the beam path P and deflects ions of undesired charge to mass ratios away from the beam path P. Once through the mass analyzer 138, the ion beam 108 is directed though a resolving aperture 140, wherein the ion beam 108 may be accelerated, decelerated, focused or otherwise modified for implantation into the workpiece 110 positioned within an end station 144.

The ion source of the present invention comprises components of a standard IHC ion source of the type manufactured and sold by Axcelis Technologies, of Beverly, Mass., wherein the ion source plasma chamber includes a standard arc chamber, configured with a standard anode, extraction system and source feed tube. The internally heated cathode element of the standard IHC source is removed and replaced with a small electron source plasma chamber mounted in its place, which contains components similar to a standard IHC ion source of the type manufactured and sold by Axcelis Technologies, including an arc chamber, a standard internally heated cathode element and a source feed tube.

The foregoing descriptions of the preferred embodiments of the disclosure have been presented for purposes of illustration and description. It is not intended to be exhaustive or to limit the disclosure to the precise forms disclosed. Obvious modifications or variations are possible in light of the above teachings. The embodiments were chosen and described to provide the best illustration of the principles of the disclosure and its practical applications to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally and equitably entitled.

What is claimed:

1. A process for modifying a pattern formed by extreme ultraviolet lithography comprising:
forming the pattern comprising trench and/or line features;
depositing a sacrificial liner layer by ion beam onto sidewalls of the trench and/or line features, wherein the trench and/or line features are aligned in a longitudinal direction corresponding to a length dimension of the trench and/or line features;
rotating the pattern 90° such that the trench and/or line features are orthogonally aligned to the longitudinal direction; and
directionally etching the pattern to form a modified pattern.

2. The process of claim 1, wherein directionally depositing the sacrificial liner layer and etching utilize a double plasma ion source to produce an ion beam from a gas supply configured to directionally deposit the sacrificial liner layer and directionally etch the pattern to form the modified pattern.

3. The process of claim 1, wherein deposition of the sacrificial line is non-directional and may be executed in a separate chamber and/or tool while the etch is directional.

4. The process of claim 1, wherein depositing the sacrificial liner layer and directionally etching are generated in a radio frequency (RF), microwave (MW), electron cyclotron resonance (ECR) plasma ion source.

5. The process of claim 2, wherein the gas supply configured to directionally deposit the sacrificial liner layer comprises silanes, or siloxanes.

6. The process of claim 2, wherein the gas supply configured to etch the pattern comprises SiF₄ and the double plasma ion source is configured to generate SF₃⁺.

7. The process of claim 1, wherein the sacrificial liner layer is removed during the etching.

8. The process of claim 1, wherein depositing the sacrificial liner layer by ion beam onto the sidewalls comprises depositing the sacrificial liner layer onto a selected one of the sidewalls in the longitudinal direction followed by 180° rotation and depositing the sacrificial liner layer onto the other one of the sidewalls in the longitudinal direction.

9. The process of claim 1, wherein the trench feature is rotated 90° such that a selected end of the trench feature is directionally etched before the sacrificial liner layer has been partially or completely removed to form substantially square profile followed by rotation of the trench feature by 180° to directionally etch another end of the trench feature at the other end.

10. The process of claim 8, wherein the trench and/or line feature further comprises one or more bridge defects removed by the directional etching.

11. The process of claim 1, wherein directionally depositing the sacrificial liner layer and directional etching is at a wafer tilt of 45 to 70°.

12. The process of claim 1 further comprising in situ cleaning subsequent to forming the modified pattern to remove residues.

13. A process to modify a pattern comprising circular vias, the process comprising:
directionally etching the pattern comprising circular vias in a first direction;
rotating the pattern 90° and directionally etching the pattern comprising circular vias in a second direction;
repeating rotating the pattern 90° and directionally etching the pattern comprising circular vias in third and fourth directions;
rotating the pattern 45° and directionally depositing a liner layer in a fifth direction;
rotating the pattern 90° and directionally depositing the liner layer in a sixth direction;
repeating rotating the pattern 90° and directionally etching the pattern comprising circular vias in seventh and eighth directions to form a modified pattern of the circular vias having a substantially square profile.

14. The process of claim 13, wherein the directionally etching and directionally depositing the liner layer utilizes a double plasma ion source to produce an ion beam from a gas supply configured to directionally etch and directionally deposit the liner layer.

15. The process of claim 13, wherein directionally depositing the liner layer and directionally etching is at a wafer tilt of 45 to 70°.

16. A process to reduce tip-to-tip spacing between lines and/or trenches from using extreme ultraviolet lithography, the process comprising:
patterning line, via and/or trench features using extreme ultraviolet lithography along a longitudinal direction, wherein adjacent lines, vias and/or trench features along a common axis in the longitudinal direction are spaced apart from one another;
directionally depositing a sacrificial liner layer by ion beam onto sidewalls along a longitudinal direction of the patterned lines, vias and/or trench features;
rotating the patterned lines, vias and/or trench features 90° such that the patterned lines and/or trench features are aligned in a y-direction; and
directionally etching the pattern in the y-direction to reduce the spacing between the adjacent lines, vias and/or trench features.

17. The process of claim 16, wherein directionally depositing the sacrificial liner layer and etching utilize a double plasma ion source to produce an ion beam from a gas supply configured to directionally deposit the sacrificial liner layer and directionally etch.

18. The process of claim 17, wherein the gas supply configured to directionally deposit the sacrificial liner layer comprises silanes, or siloxanes.

19. The process of claim 16, wherein the gas supply configured to etch comprises SiF₄ and the double plasma ion source is configured to generate SF₃⁺.

20. The process of claim 16, wherein directionally depositing the sacrificial liner layer and directional etching is at a wafer tilt of 45 to 70°.
